(19) United States
(12) Patent Application Publication
(10) Pub. No.: US 2016/0251992 A1
(43) Pub. Date: Sep. 1, 2016

(54) FLEXIBLE THERMOELECTRIC GENERATOR MODULE AND METHOD FOR PRODUCING THE SAME

(71) Applicant: KOREA UNIVERSITY RESEARCH AND BUSINESS FOUNDATION, Seoul (KR)

(72) Inventors: Sang Sig KIM, Seoul (KR); Kyoung Ah CHO, Seoul (KR); Jin Yong CHOI, Seoul (KR)

(73) Assignee: KOREA UNIVERSITY RESEARCH AND BUSINESS FOUNDATION, Seoul (KR)

(21) Appl. No.: 14/840,976

(22) Filed: Aug. 31, 2015

(30) Foreign Application Priority Data
Feb. 27, 2015 (KR) 10-2015-0028220

(51) Int. Cl. F01N 5/02; H01L 35/34; H01L 35/32

(52) U.S. Cl. CPC F01N 5/025; H01L 35/32; H01L 35/34

(57) ABSTRACT

The present invention provides a thermoelectric generator module including one or more module unit bodies disposed between a hot source and a cold source to serve as fundamental structures for performing thermoelectric power generation, wherein the module unit bodies are disposed on a exhaust pipe interposed between the hot source and the cold source, and provides a method of manufacturing the thermoelectric generator module.

### CROSS-REFERENCE TO RELATED APPLICATIONS

This application claims the benefit of Korean Patent Application No. 10-2015-0028220, filed on Feb. 27, 2015 in the Korean Intellectual Property Office, which is incorporated herein by reference in its entirety.

### BACKGROUND OF THE INVENTION

1. Field of the Invention

The present invention relates to a thermoelectric generator module, and more particularly, to such a thermoelectric generator module which has a structure of improving the easiness of manufacture through a solution process.

2. Description of Related Art

In general, thermoelectric effect means a reversible and direct energy conversion between heat and electricity. The thermoelectric effect is classified into the Peltier effect which is applied to a cooling field using a temperature difference between both ends of a material formed by a current applied from the outside, and the Seebeck effect which is applied to a power generation field using an electromotive force generated from a temperature difference between both ends of a material.

Thermoelectric cooling is a vibration-free and low-noise eco-friendly cooling technology which does not make use of a refrigerant gas causing environmental problems, and application areas can be widen to a general-purpose cooling field including a refrigerator, an air conditioner or the like through the development of a high-efficiency thermoelectric cooling material.

Also, in the case of a thermoelectric power generation technology employing the Seebeck effect, if a thermoelectric material is applied to heat dissipating equipment or a relevant section in an automobile engine, an industrial plant or the like, power generation can be performed by a temperature difference between both ends of the material. In spacecrafts for remote planets in which the use of a solar energy is impossible, such a thermoelectric power generation system is already in operation.

The thermoelectric generator module is a circuit in which p-type or n-type conductors or semiconductors are electrically connected with each other end to end so that current is caused to flow by means of a thermo-electromotive force generated when one side of the module is used as a hot source and the other side of the module is used as a cold source,

Currently, the development of a thermoelectric generator module using nanoparticles is in progress to achieve the compactness of such a thermoelectric generator module. An example of this technology is disclosed in Korean Patent No. 1249292 (registered on Mar. 26, 2013, and hereinafter, referred to as ‘prior art 1’) entitled “Thermoelectric Device, Thermoelectric Device Module, and Method of Forming The Thermoelectric Device”.

The thermoelectric device of the prior art 1 includes: a first conductive film of first semiconductor nanoparticles including at least one first barrier region; a second conductive film of second semiconductor nanoparticles including at least one second barrier region; a first electrode connected to one end of the first semiconductor nanoparticle; a second electrode connected to one end of the second semiconductor nanoparticle; and a common electrode connected to the other end of the first semiconductor nanoparticle and the other end of the second semiconductor nanoparticle.

A thermoelectric device module including the thermoelectric device of the prior art 1 is configured such that the semiconductor nanoparticle and the second semiconductor nanoparticle serve as a bridge which interconnects the first electrode, the second electrode, and the common electrode. Such a bridge forming structure has a limitation in improving the performance and the degree of freedom of design of the thermoelectric device module in that the manufacturing process is made complicated as well as only the manufacture of an alternative structure is permitted.

In addition, as an example of a method of manufacturing a thermoelectric device using nanoparticles, there is disclosed Korean Patent Laid-Open Publication No. 10-2012-71254 (laid-open on Jul. 2, 2012, and hereinafter, referred to as ‘prior art 2’) entitled “Thermoelectric Device and Method of Manufacturing The Same.

The manufacturing method of a thermoelectric device of the prior art 2 includes: a structuring forming step of depositing and patterning a semiconductor layer on a flexible substrate to form a first nanoparticle film pattern, a second nanoparticle film pattern, a low-temperature section, and a high-temperature section; a nanoparticle forming step of ion-injecting a first conductive type material and a second conductive type material into the first nanoparticle film pattern and the second nanoparticle film pattern, respectively; an insulation layer forming step of depositing and patterning an insulation material on the entire surface of the flexible substrate to form an insulation layer on the first nanoparticle film and the second nanoparticle film; a first metal layer forming step of depositing and patterning a metal material on the entire surface of the flexible substrate to form a first metal layer on the insulation layer on the first nanoparticle film; and a metal layer forming step of depositing and patterning a metal material on the entire surface of the flexible substrate to form a second metal layer on the insulation layer on the second nanoparticle film.

However, the prior art 2 also entails a problem in that since various steps are required which include the pattern formation, the insulation layer formation, the metal layer formation, and the like in order to form the first nanoparticle film and the second nanoparticle film, the manufacturing process is complicated, and there is a limitation in the increase in the performance of the thermoelectric device module similarly to the prior art 1. In addition, the manufacturing method of a thermoelectric device of the prior art 2 is a manufacturing method employing an alternative structure, and thus a problem is caused in that the degree of freedom of design of the thermoelectric device module is decreased.

### SUMMARY OF THE INVENTION

Accordingly, the present invention has been made to solve the above-mentioned problems caused by a complicated manufacturing process the prior arts, and it is an object of the present invention to provide a thermoelectric generator module and a method of manufacturing the same, in which a structure and a manufacturing process of the thermoelectric generator module are implemented using a solution process so that the manufacturing cost can be optimized, and in which the diversity of arrangement can be secured through a serial connection structure in which a plurality of module unit bodies is connected to each other so that the degree of freedom of design can be increased.

To achieve the above object, in one aspect, the present invention provides a thermoelectric generator module including one or more module unit bodies 10 disposed between a hot source and a cold source to serve as fundamental structures for performing thermoelectric power generation, wherein the module unit bodies 10 are disposed on a flexible substrate 100 interposed between the hot source and the cold source, and wherein each of the module unit bodies 10 includes: at least two first electrodes disposed at one of the hot source and the cold source so as to be spaced apart from each other; a second electrode disposed at the other of the hot source and the cold source so as to be spaced apart from the first electrodes; a first nanoparticle film 50 configured to interconnect one of the first electrodes and the second electrode and composed of an n-type or p-type semiconductor; and a second nanoparticle film 60 composed of a conductor or semiconductor of a type different from the type of the semiconductor forming the first nanoparticle film 50, and the second nanoparticle film 50 being connected at one end thereof to one of the two first electrodes and connected at the other end thereof to the second electrode so as to be space apart from the first nanoparticle film 50.

In the thermoelectric generator module, the first electrodes and the second electrode may be disposed on a co-plane, at least one of the first electrodes may be connected to one of first electrodes in an adjoining module unit body, and at least one of the first electrodes, the second electrode, the first nanoparticle film 50, and the second nanoparticle film 60 of the module unit body 10 may form a “ [symbol] ” shape.

In the thermoelectric generator module, the module unit bodies including the module unit body consisting of the first electrodes, the second electrode, the first nanoparticle film 50, and the second nanoparticle film 60, which form the “ [symbol] ” shape, may be consecutively disposed in series on the flexible substrate 100 to capture any one heat source.

In the thermoelectric generator module, a heat shielding protective layer may be disposed on one side of the flexible substrate between the first electrodes and the second electrode.

In the thermoelectric generator module, the heat shielding protective layer may include at least one of a ceramic based material such as ZrO₂, SiO₂, Al₂O₃, TiO₂, SiC or ZrO₂ and polymer.

In the thermoelectric generator module, the flexible substrate may be formed of any one selected from among Polydimethylsiloxane (PDMS), polyimide, polycarbonate, Poly(methyl methacrylate) (PMMA), cyclic olefin copolymer (COC), parylene, polyethylene terephthalate (PET), polybutylene terephthalate (PBT), polysilane, polysiloxane, polysilazane, polycarbosilane, polyacrylate, polymethacrylate, polymethylacrylate, polyethylacrylate, polyethylmetacrylate, cyclic olefin polymer (COP), polyethylene (PE), polyprophylene (PP), polystyrene (PS), polyoxymethylene (POM), poly(ether ether ketone) (PEEK), polyether sulfone (PES), polytetrafluoroethylene (PTFE), polyvinyl chloride (PVC), polyvinylidene fluoride (PVDF), and perfluoroalkyl ethyl acrylate (PFA), or a combination thereof.

In the thermoelectric generator module, the first nanoparticle film and the second nanoparticle film may include a chalcogenide compound.

In the thermoelectric generator module, the first nanoparticle film may include at least one chalcogenide compound selected from the group consisting of HgTe, Sb₂Te₃, Bi₂Te₃, and PbTe.

In the thermoelectric generator module, the second nanoparticle film may include at least one chalcogenide compound selected from the group consisting of HgSe, Sb₂Se₃, Bi₂Se₃, PbSe, and PbS.

In another aspect, the present invention provides a method of manufacturing a thermoelectric generator module, the method including: a nanoparticle solution provision step of providing a first nanoparticle solution comprising a first nanoparticle composed of an n-type or p-type semiconductor and a second nanoparticle solution comprising a second nanoparticle composed of a p-type or n-type semiconductor; a first electrode pattern formation step of forming a pattern 200 for deposition of a conductive layer for first electrodes by performing a photolithography process on a flexible substrate 100; a first electrode deposition step of depositing a conductive layer on the pattern 200 to form the first electrodes 300; a first nanoparticle film pattern formation step of forming a pattern 400 for formation of a first nanoparticle film connected to the first electrodes by performing the photolithography process on at least one of the first electrodes 300 formed on the flexible substrate 100; a first nanoparticle film formation step of spin-coating the first nanoparticle solution on the pattern 400 to form the first nanoparticle film 500; a second nanoparticle film pattern formation step of forming a pattern 600 for formation of a second nanoparticle film that is alternately arranged with the first nanoparticle film so as to be spaced apart from the first nanoparticle film and is connected to the first electrode by performing the photolithography process on at least one of the first electrodes 300; a second nanoparticle film formation step of spin-coating the second nanoparticle solution on the pattern 600 to form the second nanoparticle film 700; a second electrode pattern formation step of forming a pattern 800 for deposition of a conductive layer for the second electrode by performing a photolithography process on the other sides of the first and second nanoparticle films 500 and 700; a second electrode deposition step of depositing a conductive layer on the pattern 800 to form the second electrodes 900; and a protective layer formation step of forming a heat shielding protective layer 800 on the first and second nanoparticle films 500 and 700 between the first electrode 300 and the second electrode 900.

In the thermoelectric generator module manufacturing method, the first nanoparticle solution and the second nanoparticle solution may include a chalcogenide compound.

In the thermoelectric generator module manufacturing method, the first nanoparticle solution may include at least one chalcogenide compound selected from the group consisting of HgTe, Sb₂Te₃, Bi₂Te₃, and PbTe.

In the thermoelectric generator module manufacturing method, the second nanoparticle solution may include at least one chalcogenide compound selected from the group consisting of HgSe, Sb₂Se₃, Bi₂Se₃, PbSe, and PbS.

In the thermoelectric generator module manufacturing method, in the first nanoparticle film formation step and the second nanoparticle film formation step, the rotational speed of the flexible substrate may be in the range between the 500 rpm and 7000 rpm.

In the thermoelectric generator module manufacturing method, during the rotation of the flexible substrate, a speed change of the flexible substrate to predetermined different first and second rotational speeds may occur for a predetermined time, wherein the first rotational speed may be lower than the second rotational speed, and the rotation time of the first rotational speed may be shorter than the rotation time of the second rotational speed, and wherein the ratio of the first rotational speed to the second rotational speed may be below 1:12, and the ratio of the rotation time of the first rotational speed to the rotation time of the second rotational speed may be below 1:8.

In still another aspect, the present invention provides a thermoelectric generator module manufactured by any one of the methods of manufacturing the thermoelectric generator module.

The thermoelectric generator module and the method of manufacturing the same according to the embodiments of the present invention as constructed above have the following advantageous effects.

The manufacturing process and structure of the thermoelectric generator module including the nanoparticle films can be simplified through the solution process.

In addition, the manufacturing cost of the thermoelectric generator module can be reduced and the thermoelectric generator module can be developed as a compact structure through the simplification of the manufacturing process and structure of the thermoelectric generator module.

Moreover, the thermoelectric generator module can be arranged in various patterns through the serial connection structure using electrodes and nanoparticles, thus leading to an increase in the degree of freedom of design for improving the thermoelectric generation efficiency, and maximizing the thermoelectric performance by enabling a serial connection arrangement through the implementation of a large area.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a schematic view illustrating a configuration of module unity bodies of a thermoelectric generator module according to an embodiment of the present invention;

FIG. 2A to 2D respectively illustrate a state in which the module unity bodies of a thermoelectric generator module of the present invention are arranged;

FIG. 3 is a graph illustrating the relationship between a temperature difference and a voltage change in an example of a state in which the module unity bodies of a thermoelectric generator module of the present invention are arranged consecutively;

FIGS. 4, 5A to 5C and 6 are a schematic partial top plan view, a test state view and a diagram illustrating the relationship between the number of the module unit bodies and a voltage in an example of a thermoelectric generator module of the present invention;

FIG. 7 is a partial top plan view illustrating a thermoelectric generator module according to another embodiment of the present invention;

FIG. 8 is a schematic top plan view illustrating a thermoelectric generator module according to still another embodiment of the present invention;

FIG. 9A to 9D respectively illustrate a test state view and a partially enlarged view of a thermoelectric generator module of present invention shown in FIG. 8;

FIG. 10 is a diagram illustrating the relationship between voltage and time of a thermoelectric generator module shown in FIGS. 9A to 9D;

FIG. 11 is a schematic block diagram of a health care unit to which an example of a thermoelectric generator module of the present invention is applied;

FIG. 12 is a schematic diagram illustrating another example of a thermoelectric generator module of the present invention; and

FIG. 13A to 13N are state views illustrating a process of manufacturing a thermoelectric generator module of the present invention.

### EXPLANATION ON REFERENCE NUMERALS OF MAIN ELEMENTS IN THE DRAWINGS

1: thermoelectric generator module
10: module unit body
20: first electrode
30: second electrode
50: first nanoparticle film
60: second nanoparticle film
T_{H}, T_{C}: hot and cold sources
100: flexible substrate

### DESCRIPTION OF THE PREFERRED EMBODIMENTS

Hereinafter, a thermoelectric generator module and a method of manufacturing the same according of the present invention will be described in detail with reference to the accompanying drawings.

The drawings to be provided below are provided by way of example so that the idea according to the present invention can be sufficiently transferred to those skilled in the art to which the present invention pertains. Therefore, the present invention is not limited to the drawings presented below, and may be embodied in other forms.

In addition, unless otherwise defined, the terms as used herein have the same meanings as those generally understood by those skilled in the art to which the present invention pertains. In the following description and the accompanying drawings, the detailed description on known related functions and constructions will be omitted to avoid unnecessarily obscuring the subject matter of the present invention hereinafter.

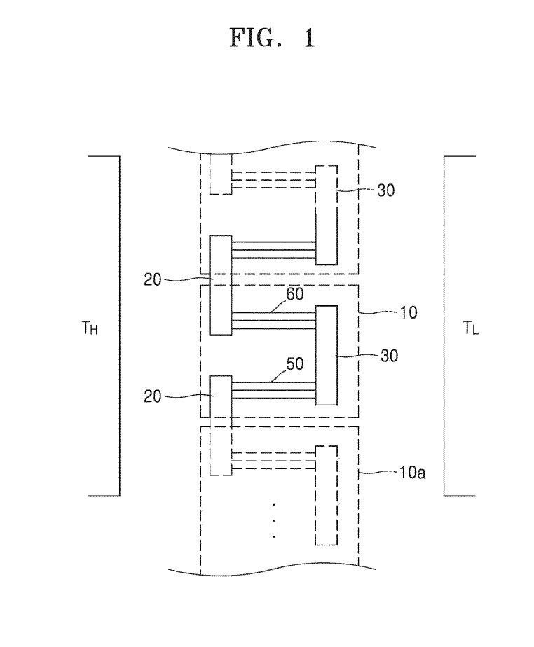

FIG. 1 is a schematic view illustrating a configuration of module unity bodies of a thermoelectric generator module according to an embodiment of the present invention.

The thermoelectric generator module of the present invention includes one or more module unit bodies 10 as a basic fundamental structure for thermoelectric power generation. In other words, the thermoelectric generator module of the present invention may take a structure having a single module unit body, and may be constructed in various manners depending on a design specification, such as taking an assembly structure composed of a plurality of module unit bodies.

Referring to FIG. 1, the thermoelectric generator module of the present invention includes one or more module unit bodies 10 which are disposed between two heat sources having different temperatures to cause a temperature difference therebetween.

The module unit body 10 which serves as a basic fundamental structure for performing thermoelectric power generation includes a first electrode 20, a second electrode 30, a first nanoparticle film 50, and a second nanoparticle film 60. The module unit bodies 10 of the present invention are disposed on a flexible substrate 100 so that certain flexibility can be provided to maximize utility of the thermoelectric generator module.

More specifically, the thermoelectric generator module of the present invention further includes the flexible substrate 100. Herein, the flexible substrate is generally defined as a substrate or a thin film. The flexible substrate may be formed of any one selected from among Polydimethylsiloxane (PDMS), polyimide, polycarbonate, Poly(methyl methacrylate) (PMMA), cyclic olefin copolymer (COC), parylene, polyethylene terephthalate (PET), polybutylene terephthalate (PBT), polysilane, polysiloxane, polysilazane, polycarbosilane, polyacrylate, polymethacrylate, polymethylacrylate, polyethylacrylate, polyethylmetacrylate, cyclic olefin polymer (COP), polyethylene (PE), polyprophylene (PP), polystyrene (PS), polyoxymethylene (POM), poly(ether ether ketone) (PEEK), polyether sulfone (PES), polytetrafluoroethylene (PTFE), polyvinyl chloride (PVC), polyvinylidene fluoride (PVDF), and perfluoroalkyl ethyl acrylate (PFA), or a combination thereof.

The first electrode 20 is disposed at a hot source (T_{H}), and the second electrode 30 is disposed at a cold source (T_{C}) so as to be spaced apart from the first electrode 20 by a predetermined distance. The first electrode 20, i.e., two first electrodes 20 are disposed at the hot source (T_{H}) so as to be spaced apart from each other. Although it has been shown in this embodiment that the module unit body 10 includes two first electrodes 20 and one second electrode 30, a vice-versa configuration is also possible, if necessary. In other words, it is obvious in this embodiment that the module unit body 10 may include a structure in which one first electrode 20 and two second electrodes 30 are disposed.

In this embodiment, although the first electrodes 20 are disposed at the hot source (T_{H}) side and the second electrode 30 is disposed at the cold source (T_{C}) side, this configuration is merely an example, and the module unit body 10 may be modified in various manners, such as taking a vice-versa configuration.

The first nanoparticle film 50 and the second nanoparticle film 60 may be formed in various manners, but the nanoparticle film of the thermoelectric generator module according to an embodiment of the present invention is formed by a solution process, especially a spin-coating method to solve the restrictions of the substrate so that the module unit body 10 can be implemented on a substrate made of a flexible material such as the flexible substrate 100 of the present invention.

The first nanoparticle film 50 interconnects the first electrodes 20 and the second electrode 30 and is composed of an n-type or p-type semiconductor. The second nanoparticle film 60 is composed of a p-type or n-type semiconductor. The first nanoparticle film 50 and the second nanoparticle film 60 are disposed so as to be spaced apart from each other in such a manner that they are connected at one ends thereof to the first electrodes and are connected at the other ends thereof to the second electrode. In other words, when the first nanoparticle film 50 is composed of the n-type semiconductor, the second nanoparticle film 60 is composed of the p-type semiconductor. Contrarily, when the first nanoparticle film 50 is composed of the p-type semiconductor, the second nanoparticle film 60 is composed of the n-type conductor or semiconductor.

The first nanoparticle film 50 and the second nanoparticle film 60 include a chalcogenide compound. More specifically, in an embodiment of the present invention, a first nanoparticle included in the first nanoparticle film includes at least one chalcogenide compound selected from the group consisting of HgTe, Sb₂Te₃, Bi₂Te₃, and PbTe, and a second nanoparticle included in the second nanoparticle film 60 includes at least one chalcogenide compound selected from the group consisting of HgSe, Sb₂Se₃, Bi₂Se₃, PbSe, and PbS. In this embodiment, first nanoparticle film 50 and the second nanoparticle film 60 were formed by a spin-coating method in which nanoparticles formed by a colloid method are re-dispersed in a nanoparticle solution.

The first nanoparticle film 50 is connected at one end thereof to one of the first electrodes 20 and is connected at the other end thereof to the second electrode 30. In addition, the second nanoparticle film 50 is connected at one end thereof to the other of the first electrodes 20 and is connected at the other end thereof to the second electrode 30 so as to be spaced apart from the first nanoparticle film 50.

In the module unit body 10 of the thermoelectric generator module of the present invention as constructed above, the first electrodes 20 are disposed so as to be opposed to the second electrode 30, and the first nanoparticle film 50 and the second nanoparticle film 60 are disposed so as to interconnect the first electrodes 20 and the second electrode 30. In this embodiment as shown in FIG. 1, the first electrodes 20 and the second electrode 30 are disposed on a co-plane. The first electrodes 20 and the second electrode 30 are disposed so as to be spaced apart from each other in such a manner that the first nanoparticle film 50 and the second nanoparticle film 60 are disposed between the first electrodes 20 and the second electrode 30 so as to be spaced apart from each other. At least one of the first electrodes is connected to one of first electrodes 20 in an adjoining module unit body 10a, and at least one of the first electrodes 20, the second electrode 30, the first nanoparticle film 50, and the second nanoparticle film 60 of the module unit body 10 can form a “ [symbol] ” shape. In other words, although the module unit bodies 10 can have various arrangement structures, at least one of the module unit bodies 10 of the thermoelectric generator module of the present invention takes a structure in which the first electrode 20 and the second electrode 30 are disposed in parallel with each other so as to be spaced apart from each other in such a manner that two first electrode 20 are provided and one second electrode 30 is provided so that when projected to the same segment relative to the longitudinal direction, the first electrode and the second electrode 30 are partially superposed with each other to cause the centers of the first electrode 20 and the second electrode 30 to be spaced apart from each other. In addition, the consecutive connection arrangement of a plurality of module unit bodies is achieved so that any one of the first electrodes 20 is connected to one of first electrodes 20 in another adjoining module unit body 10a. Resultantly, at least one of the first electrodes, the second electrode, the first nanoparticle film 50, and the second nanoparticle film 60 of the module unit body 10 forms a “ [symbol] ” shaped structure.

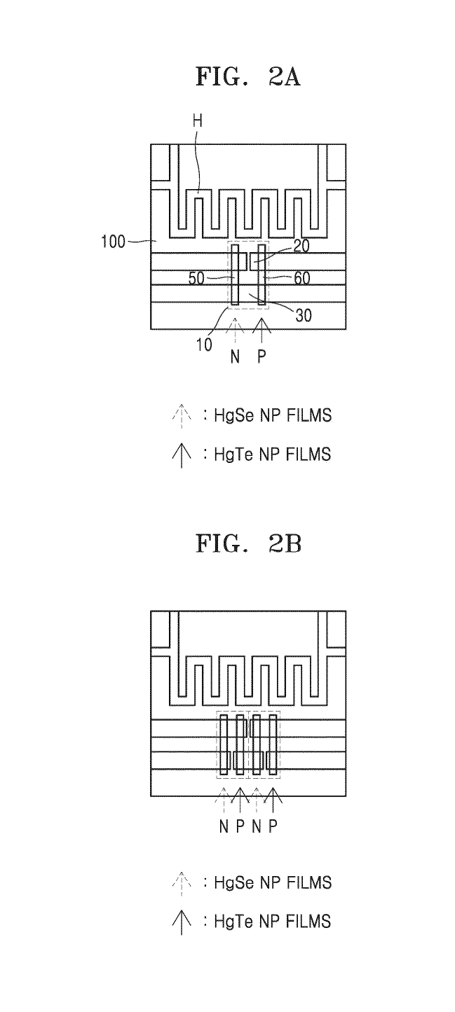

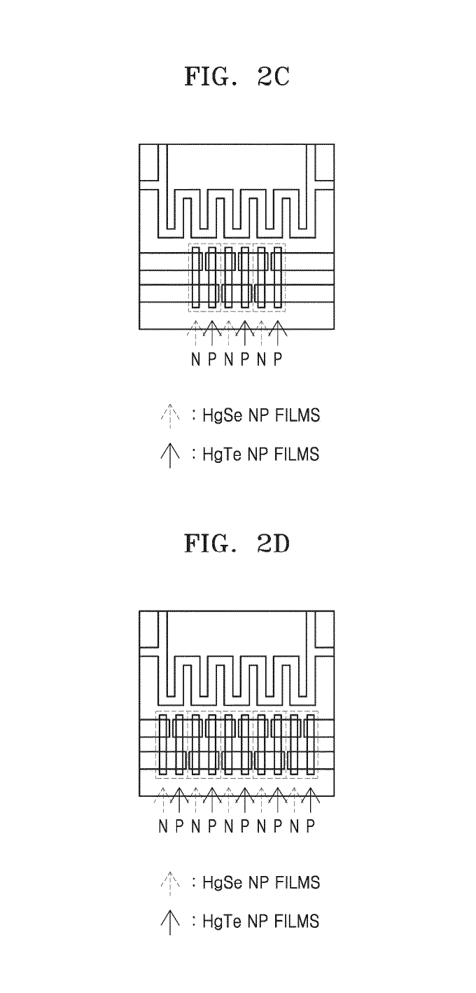

The module unit bodies of the thermoelectric generation module of the present invention may have a structure in which the module unit bodies are connected in a row depending on a design specification. FIGS. 2A to 2D show an example of the thermoelectric generation module having a structure in which the number of the module unit bodies 10 is increased to one, two, three, and five. In the drawing, a heater hotwire line H that artificially forms a hot source side to perform a performance test is disposed on a top of the module unit body 10. The number of the module unit bodies 10 is increased through such a consecutive serial arrangement structure so that predetermined voltage and current can be formed depending on a design specification.

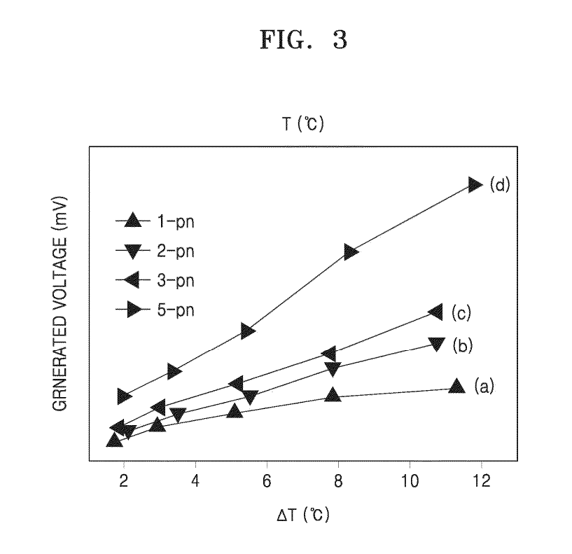

FIG. 3 shows a change in the voltage according to a temperature difference for FIGS. 2A to 2D, which indicates a general linear increase according to an increase in the number of the module unit bodies. However, as a temperature difference between the hot source and the cold source is increased, FIG. 3 shows a linear increase pattern. FIG. 3 shows a greater increase in the voltage change as the number of the module unit bodies having the consecutive serial connection arrangement structure is increased. Thus, the module unit bodies may form a consecutive serial connection arrangement structure satisfying a certain design specification through a selective combination of the number of the module unit bodies according to the required thermoelectric capacity.

Meanwhile, a heat shielding protective layer 110 is disposed on one side of the flexible substrate 100 between the first electrode 20 and the second electrode 30. The heat shielding protective layer 110 is coated on the first nanoparticle film 50 and the second nanoparticle film 60. A coverage of the heat shielding protective layer 110 extends to the first nanoparticle film 50 and the second nanoparticle film 60, and to an at least part of the first electrode or the second electrode, if necessary, to prevent first nanoparticle film 50 and the second nanoparticle film 60 from being exposed to the outside on one side of the flexible substrate 100 so that heat transfer is performed in a state in which an external effect exerted on the first nanoparticle film and the second nanoparticle film are minimized due to a temperature difference between the first electrode 20 and the second electrode 30 disposed on one side of the flexible substrate 100.

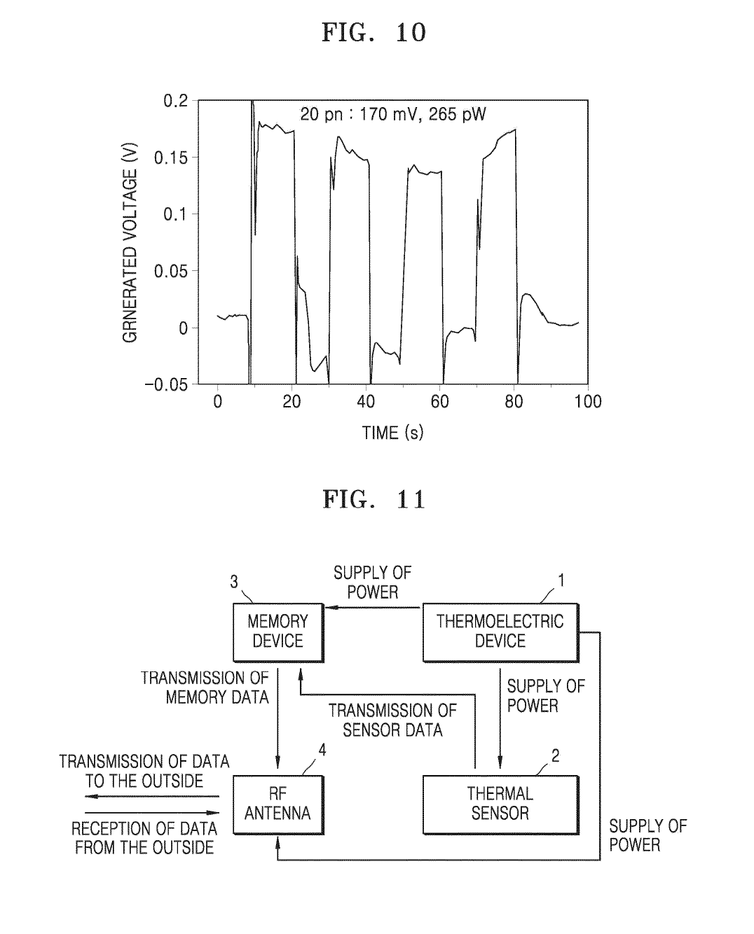

In other words, the thermoelectric generator module of the present invention has a structure in which other constituent elements are mounted on the flexible substrate 100. One or more module unit bodies 10 are mounted on the flexible substrate 100 such that the first electrodes 20 and the second electrode 30 are connected in series by means of the first nanoparticle film 50 and the second nanoparticle film 60, which serve as thermoelectric devices, and the heat shielding protective layer 110 (see FIG. 10) the completely covers the first nanoparticle film 50 and the second nanoparticle film 60 is formed between the first electrodes 20 and the second electrode 30, more specifically on one side of the flexible substrate 100.

The heat shielding protective layer 110 serves to prevent exposure thereof to other heat sources disposed on a top surface of the flexible substrate 100 to give the thermal insulation effect to the thermoelectric generator module, thereby improving the thermoelectric performance, and simultaneously prevent a damage of the constituent elements disposed on one side of the flexible substrate 100 due to introduction of foreign substances from the outside. In this embodiment, the heat shielding protective layer may include at least one of a ceramic based material such as ZrO₂, SiO₂, Al₂O₃, TiO₂, SiC or ZrO₂ and polymer having an excellent thermal insulation property to perform a heat shielding and protecting function.

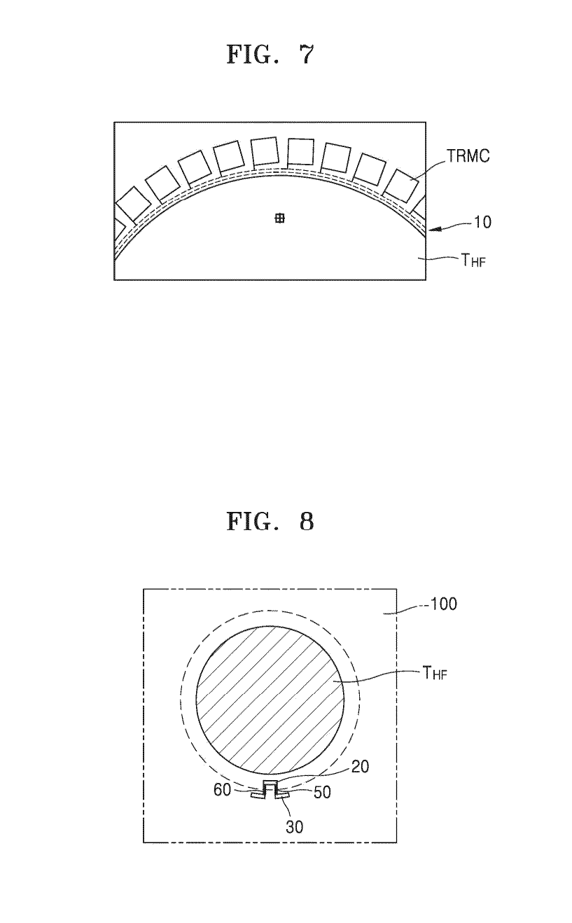

In the meantime, the thermoelectric generator module of the present invention may have a structure in which the module unit bodies including the module unit body forming such a “ [symbol] ” shape, are consecutively disposed in series on the flexible substrate 100 to capture any one heat source (see FIGS. 7 and 8). In FIG. 8, one module unit body is shown illustratively, but the module unit bodies are disposed in a repetitive serial connection manner to capture the surroundings of the heat source. In FIG. 8, a dotted line denotes a repetitive arrangement of the module unit body. Although it has been shown in this embodiment that the module unit body is disposed in a circular shape, the module unit body may be modified in various manners depending on a design specification, such as taking a square consecutive arrangement structure, an atypical arrangement structure, etc.

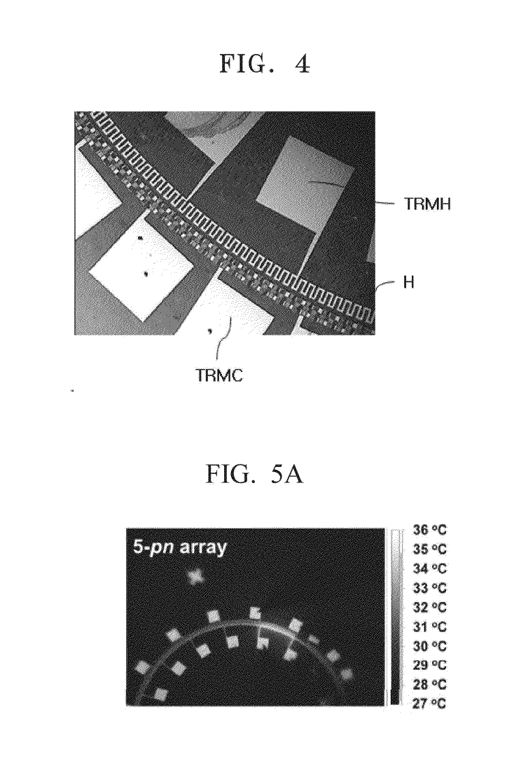

FIG. 4 shows a partial perspective view illustrating an example of the thermoelectric generator module of the present invention in which the module unit bodies 10 of the thermoelectric generator module are consecutively disposed. In FIG. 4, the thermoelectric generator module has been formed as a platform structure in which a heater hotwire line H having a heater hotwire line terminal TRMH is additionally disposed to artificially provide an heat source to perform a thermoelectric performance test, and the heater hotwire line terminal TRMH is additionally disposed so as to be connected to and withdrawn from a predetermined number of the first electrodes or the second electrodes, but this configuration may be excluded, if necessary, and the thermoelectric generator module may be constructed in various manners.

As described above, the thermoelectric generator module is constructed to form a substantial circular button structure in which a plurality of module unit bodies including the “ [symbol] ”-shaped module unit bodies 10 formed by being connected by means of the first electrodes 20, the second electrode 30, the first nanoparticle film 50 and the second nanoparticle film 60 are connected in series to form a consecutive arrangement structure.

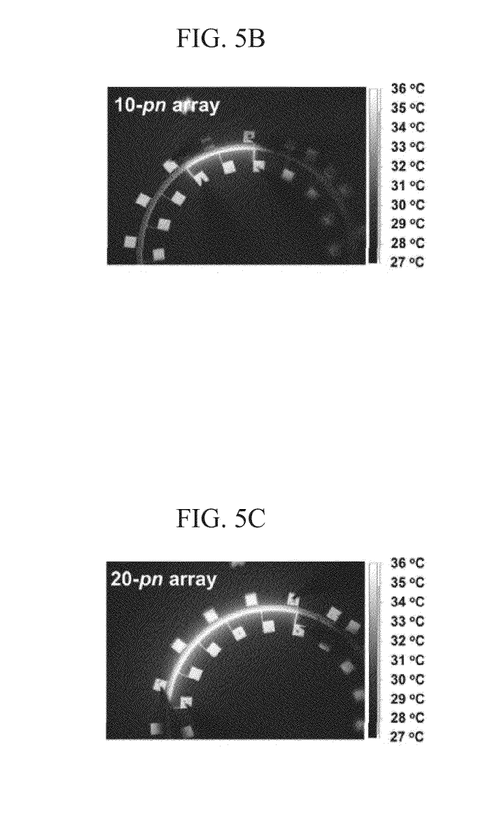

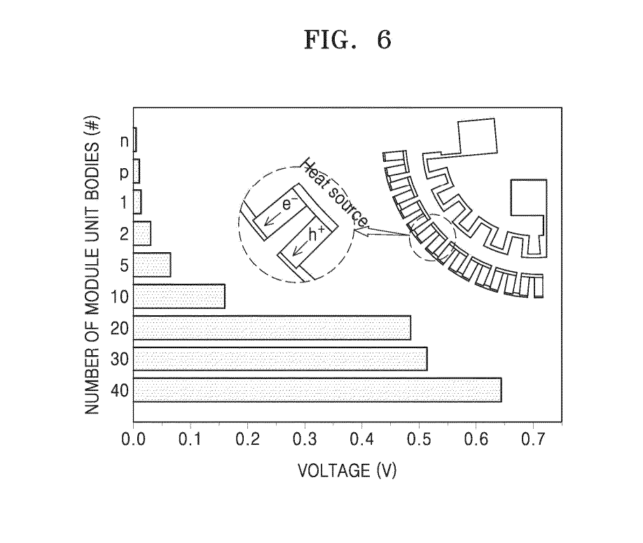

FIGS. 5A to 5C show a state view of a test process of the thermoelectric generator module including the module unit bodies having a platformed consecutive serial connection structure. In FIG. 5, in the case of the electrode terminal TRMC and the heater hotwire line terminal TRMH of the thermoelectric generator module having a platform structure, a structure is formed in which five module unit bodies are disposed between the electrode terminals TRMC and between the heater hotwire line terminals TRMH. Thus, FIGS. 5A to 5C show the artificial formation of a heat source for a structure in which a total of five module unit bodies 10 (5-pn, array) (FIG. 5A, a total of ten module unit bodies 10 (10-pn, array) (FIG. 5B, and a total of twenty module unit bodies 10 (20-pn, array) (FIG. 5C are connected in series, and the measurement state accordingly. As a result of the measurement, a voltage is shown in FIG. 6. In FIG. 6, the case is added where the number of the module unit bodies is 30 and 40, which is not shown in FIG. 5. It can be seen that a voltage difference in the case where the number of the module unit bodies is 30 and the case where the number of the module unit bodies is 40 rather indicates a nonarithmetic increase pattern as compared to other cases, but indicates a pattern in which the voltage difference is generally increased in proportion to the number of the module unit bodies.

Meanwhile, by virtue of a structure in which one heat source, i.e., a hot source T_{H} is disposed at the center of the thermoelectric generator module where the module unit bodies 10 forming such a circular ring integrated structure capture, and a cold source with a temperature lower than that of the hot source 70 is disposed at the outside of the capture region, the thermoelectric power generation is performed by the module unit bodies 10 disposed between the hot source and the cold source. A conductive material having a high thermal conductivity, e.g., a thin film pattern T_{HF} is formed at the hot source T_{H} so that transfer of heat to the first electrodes 20 of a plurality of module unit bodies 10 can be carried out rapidly and evenly. An embodiment of the thermoelectric generator module of the present invention implemented as a touch button is shown in FIG. 7 (the case where the electrode terminal TRMC are added) and FIG. 8. The thermoelectric generator module forms a structure in which a plurality of module unit bodies 10 are consecutively connected in series at the outside of the thin film pattern T_{HF} implemented at the hot source. When a user touches the thin film pattern T_{HF}, a given body temperature causes a temperature difference between the first electrode 20 and the second electrode 30 through the thin film pattern T_{HF}. The caused temperature difference forms a certain voltage at each module unit body including the first electrode, the second electrode, the first nanoparticle film and the second nanoparticle film, and forms a certain voltage corresponding to a plurality of module unit bodies connected in series. Then, an electrical signal generated by the formation of the certain voltage may be transferred to another device (not shown) connected to the plural module unit bodies to perform a predetermined switching function. In addition, the thermoelectric generator module can be modified in various manners, such as being utilized in a medical instrument or device for detecting a body temperature or a physical change.

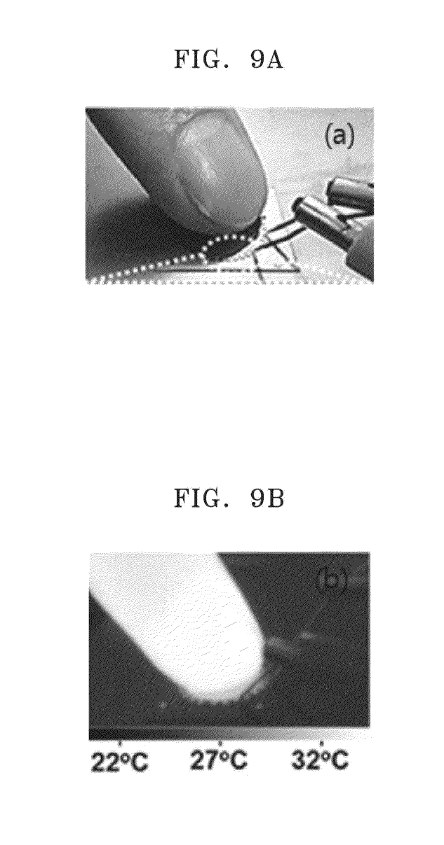

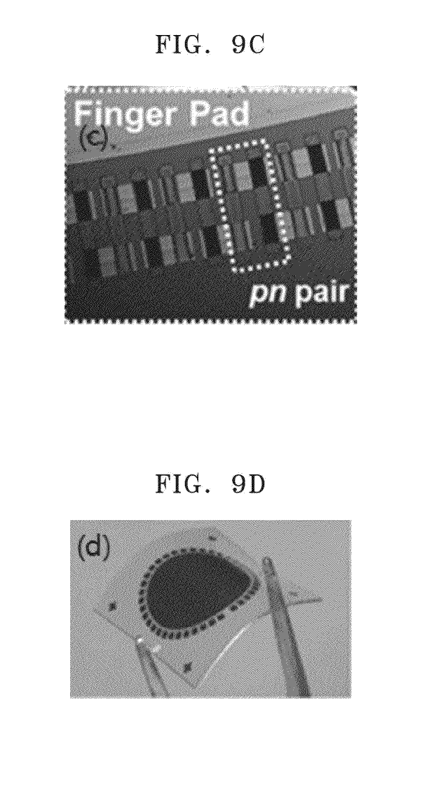

FIGS. 9 and 10 show a test state view of the thermoelectric generator module shown in FIG. 8 and a diagram illustrating the relationship between voltage and time of the thermoelectric generator module shown in FIG. 9. In this embodiment, a test was performed on 20 module unit bodies, but the number of the module unit bodies is not limited thereto and various changes are possible. When a user repeatedly perform the formation of contact and noncontact state on the thin film pattern T_{HF} using his or her finger, an electrical signal varying due to the user's body temperature and the indoor temperature is generated, and the thermoelectric generator module may be implemented as a touch button for performing a predetermined switching function using a change in the certain electrical signal.

FIG. 11 shows an example of a health care unit 1000 including the thermoelectric generator module 1 according to an embodiment of the present invention. The health care unit 1000 can include a thermoelectric generator module 1 functioning as a power source unit, a thermal sensor 2, a memory unit 3, and a wireless transmit and receive unit 4. The thermoelectric generator module 1 supplies power to the thermal sensor 2 and/or memory unit 3 and/or the wireless transmit and receive unit 4. The thermal sensor 2 transfers a detected patient's body temperature information to the memory unit 3 using the power supplied thereto from the thermoelectric generator module 1. Then, the patient's body temperature information is stored in the memory unit 3, which in turn transfers the stored body temperature information to the wireless transmit and receive unit 4. The wireless transmit and receive unit 4 can function to transmit the transferred body temperature information to an external device (not shown) or receive a signal from the external device. In addition, the thermoelectric generator module 1 may perform a power production function using the patient's body temperature as the hot source, and the wireless transmit and receive unit 4 may perform detection and transmission/reception of certain formation using the produced power so that a remote medical treatment system through transmission and reception of data between a patient and a doctor or between doctors can be constructed. In this case, the thermal sensor 2 detects a body temperature, and may take a structure in which the thermal sensor 2 forms a thermoelectric generator module including a module unit body serving as a thermoelectric device so that the thermal sensor 2 can take a structure of performing a function of detecting and transferring the body temperature information of an alternative range by the generation of power through the patient's own body temperature.

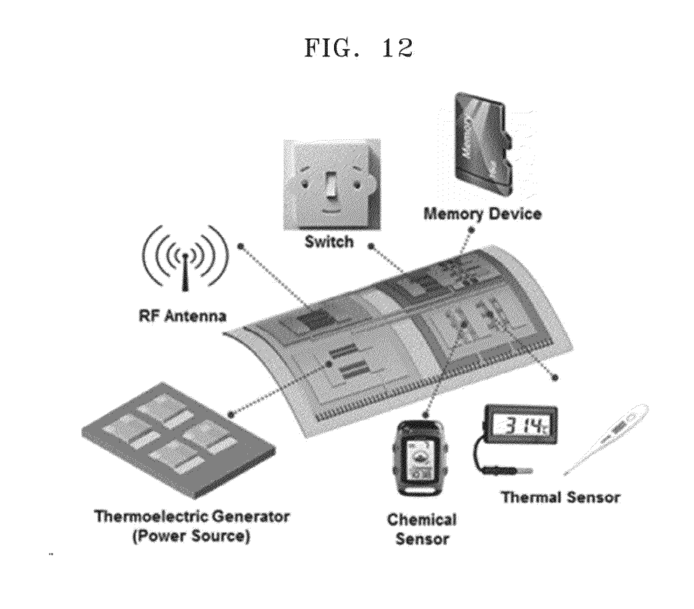

FIG. 12 shows an integrated device 2000 including the thermoelectric generator module 1 according to an embodiment of the present invention. The thermoelectric generator module may have an integrated structure in which it is implemented as a power source device, a switch, a variety of thermal temperature-based sensors and the like. The thermoelectric generator module achieves ultra-thinness of thickness thereof or minuteness of size thereof owing to the structure of the module unit bodies formed on the flexible substrate 100 to grant the infinite degree of freedom of design so that a variety of daily-life devices, industrial facilities, human body insertion medical instruments, clothes, various kinds of wearable devices can be implemented widely.

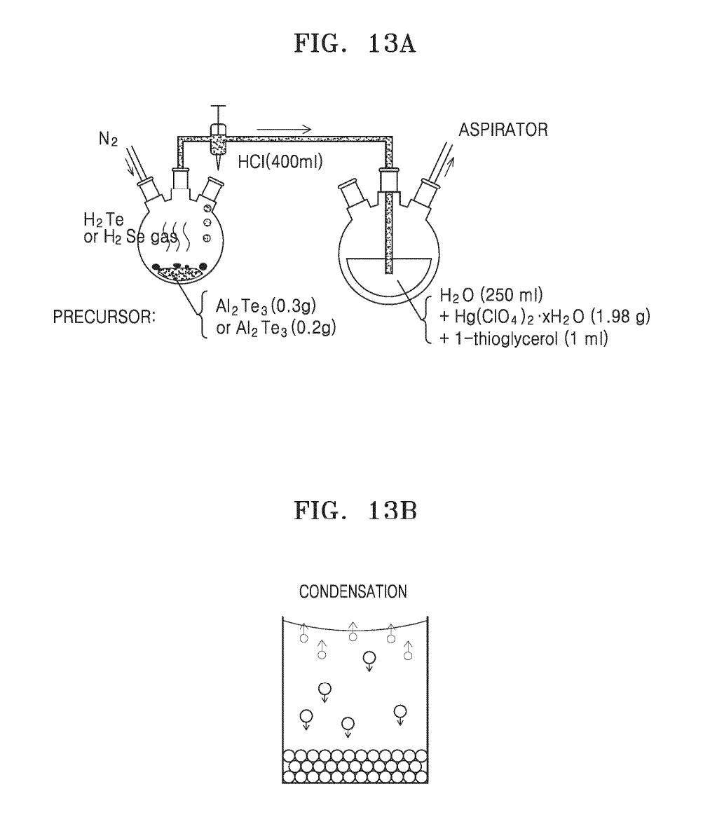

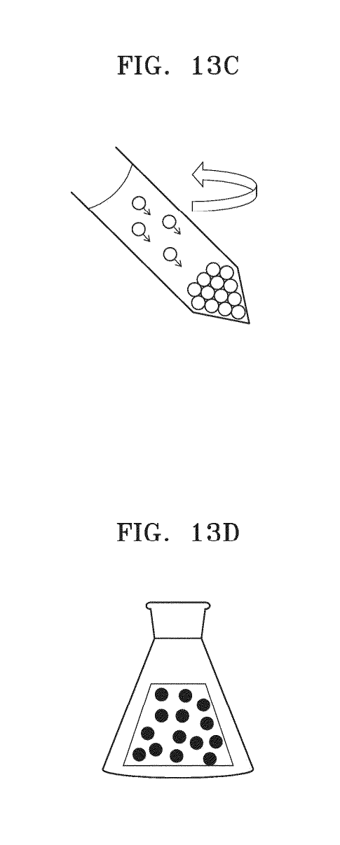

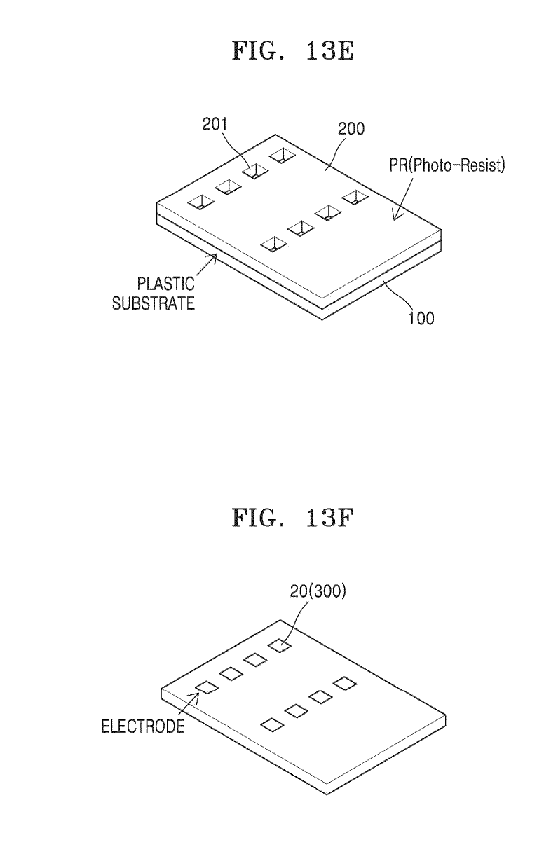

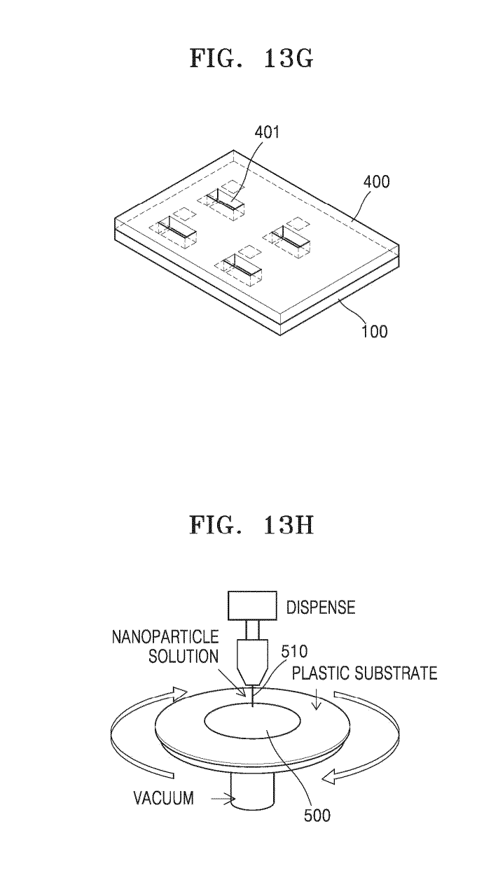

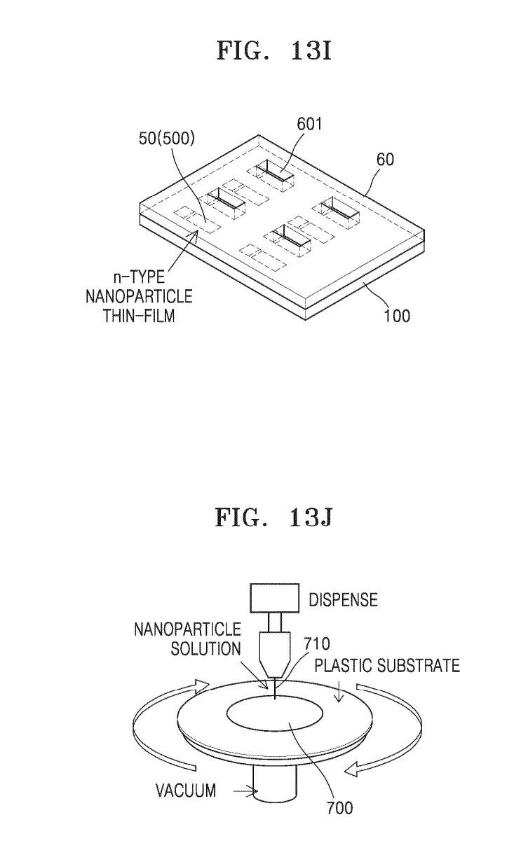

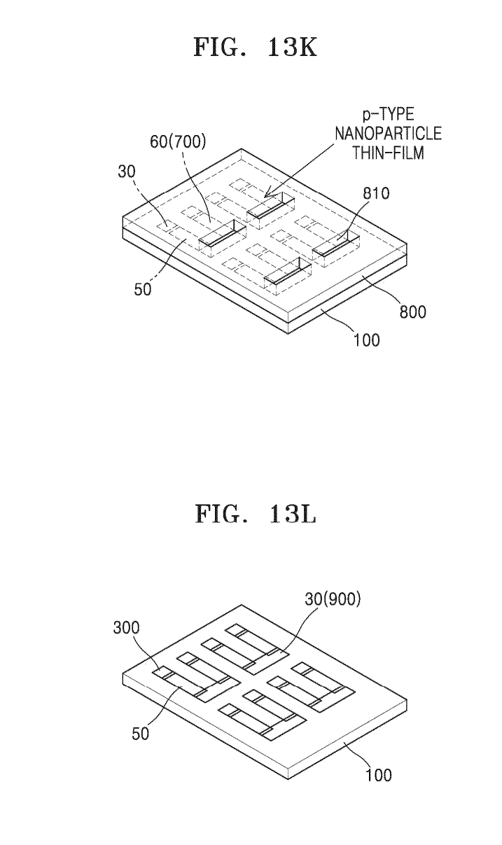

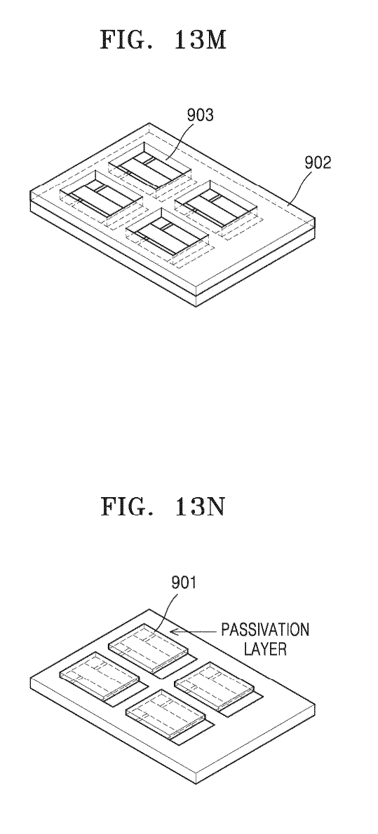

Hereinafter, a process of manufacturing a thermoelectric generator module of an embodiment of the present invention will be described with reference to the drawing. FIG. 13 shows a process of manufacturing a thermoelectric generator module of an embodiment of the present invention.

The greatest feature of the method of manufacturing the thermoelectric generator module of the present invention resides in that nanoparticles are formed on the flexible substrate by a spin-coating solution process to obtain a nanoparticle film so that the nanoparticle film is connected with each of the electrodes. The manufacturing process of the thermoelectric generator module according to the present invention will be described shortly according to steps ((a) to (j)) enumerated in an alphabetical order in FIG. 13.

Steps (a) to (d): Provision of Nanoparticle Solution for Forming Nanoparticle Film

Nanoparticles are synthesized by a colloid method, condensed and centrifuged to extract a nanoparticle powder, and then the nanoparticle powder is re-dispersed to form a nanoparticle solution.

First, in step (a), nanoparticles are synthesized by a colloid method. The nanoparticles of a semiconductor compound can be synthesized so that a first nanoparticle composed of a p-type semiconductor includes at least one chalcogenide compound (chalcogenides) selected from the group consisting of HgTe, Sb₂Te₃, Bi₂Te₃, and PbTe, and a second nanoparticle composed of an n-type semiconductor includes at least one chalcogenide compound selected from the group consisting of HgSe, Sb₂Se₃, Bi₂Se₃, PbSe, and PbS.

Specifically, as shown in FIG. 13A, 250 ml of deionized (DI) water and 1.98 g of mercury(II) perchlorate hydrate (Hg(ClO4)₂×H₂O)) are mixed and solved in a three-neck round bottom flask, to which is added 1 ml of 1-thioglycerol to prepare a solution. 1M sodium hydroxide (NaOH) is added to the prepared solution to reach a pH value of 11.4, followed by stirring continuously.

Simultaneously, 0.3 g of Al₂Te₃ or 0.2 g of Al₂Se₃ is charged as a precursor into another three-neck round bottom flask. Two three neck round bottom flasks are communicately connected to each other, and is maintained for 30 minutes at N₂ atmosphere. Thereafter, 40 ml of 4M hydrochloric acid (HCl) is added to the other flask containing the precursor. Then, as a corresponding solution is completely decolored to brown after a time lapse of about 30 minutes, the nanoparticles are synthesized.

Subsequently, in step (b), the synthesized solution (about 250 ml in this embodiment) is condensed to reach about 60 ml at about 60° C. in a water bath machine under vacuum environment.

Thereafter, in step (c), the condensed solution and an isopropyl alcohol (2-propanol) solution (1:2) are put into a test tube and are subjected to a centrifugal process. At this time, the centrifugal speed is about 1300 rpm, and a process time of about 15 minutes was spent. In this embodiment, a nanoparticle powder of about 4-7 nm was synthesized. To solve a problem of occurrence of insulation due to an organic capping material, acetone and/or methanol is put into a corresponding test tube and then the nanoparticle powder is washed and dried for about 10 minutes, thereby deriving a nanoparticle powder free of the organic capping material.

Thereafter, in step (d), 10 mg of the nanoparticle powder per 100 ul of deionized (DI) water is re-dispersed to provide the formation of the first nanoparticle solution and the second nanoparticle solution.

Step (e): Formation of First Electrode Pattern

A pattern 200 including quadrangular vias 201 for the first electrode is formed on the flexible substrate 100 using a photolithography method.

More specifically, a photoresist liquid is applied on the flexible substrate 100, and light is allowed to pass through a mask having a corresponding pattern using an exposure device to selectively irradiate light (i.e., exposure process). Then, a developer solution is sprayed onto the mask to thereby form the pattern 200 including vias 201 for formation of the first electrode on the flexible substrate 100.

It is examined by a measurement device or an optical microscope or with naked eyes whether or not a corresponding pattern is formed properly, if necessary.

Step (f): Deposition of First Electrode

When the pattern 200 is formed on the flexible substrate 100, a conductive layer having a good electrical conductivity is deposited on the pattern 200 through a known vacuum thermal evaporation process or sputter deposition process to form a first electrode layer 300.

After the formation of the first electrode layer 300, the pattern 200 formed on the flexible substrate 100 is removed through a known lift-off process. If the pattern 200 is removed from the flexible substrate 100, first electrodes 200 formed at the positions of vias (i.e., through-holes) 201 are manufactured.

Step (g): Formation of First Nanoparticle Film Pattern

A pattern 400 including rectangular vias 401 for formation of the first nanoparticle film on the flexible substrate 100 is formed using the photolithography method.

More specifically, a photoresist liquid is applied on the flexible substrate 100, and light is allowed to pass through a mask having a corresponding pattern using an exposure device to selectively irradiate light (i.e., exposure process). Then, a developer solution is sprayed onto the mask to thereby form a pattern 400 including vias 401 for formation of the first nanoparticle film on the flexible substrate 100.

Step (h): Formation of First Nanoparticle Film

When the pattern 400 is formed on the flexible substrate 100, a solution process, i.e., a spin-coating process is performed on the pattern 400 using a first nanoparticle solution to thereby form a first nanoparticle film layer 500 on one side of the flexible substrate including the pattern 400.

At this time, during the spin-coating process, the rotational speed of the flexible substrate 100, specifically a spin coater on which the flexible substrate 100 is disposed is in the range between 500 rpm and 7000 rpm.

During the rotation of the flexible substrate of the present invention, a speed change of the flexible substrate to predetermined different first and second rotational speeds (rpm1, rpm2; rpm1≠rpm2) can occur for a predetermined time. The first rotational speed rpm1 is lower than the second rotational speed rpm2 (rpm1<<rpm2), and the rotation time t1 of the first rotational speed rpm1 is shorter than the rotation time t2 of the second rotational speed rpm2 (t1<<t2). In particular, in this embodiment, the first rotational speed rpm1 is 500 rpm and the second rotational speed rpm2 is 7000 rpm. The ratio of the first rotational speed to the second rotational speed is 1:12. The rotation time t1 of the first rotational speed is 5 sec and the rotation time t2 of the second rotational speed is 40 sec. The ratio of the rotation time t1 of the first rotational speed to the rotation time t2 of the second rotational speed is 1:8.

The rotational speed and the rotation time of the rotational speed can be applied to both the first nanoparticle solution and the second nanoparticle solution. The speed change and the change in the duration time of the speed change enable uniform dispersion or distribution of a corresponding nanoparticle solution at an initial low-speed spin-coating stage as well as formation of the nanoparticle film of an ultrafilm type at a final high-speed spin-coating stage.

After the formation of the first nanoparticle film 500, the pattern 400 formed on the flexible substrate 100 is removed through a known lift-off process. If the pattern 400 is removed from the flexible substrate 100, the first nanoparticle films 50 formed at the positions of vias (i.e., through-holes) 401 are manufactured.

Step (i): Formation of Second Nanoparticle Film Pattern

A pattern 600 including rectangular vias 601 for formation of the second nanoparticle film on the flexible substrate 100 using the photolithography method is formed. The formed vias 601 are positioned between the first electrode and the second electrode which is to be formed later, and are disposed so as to be spaced apart from the position where the first nanoparticle film 50 is formed.

More specifically, a photoresist liquid is applied on the flexible substrate 100, and light is allowed to pass through a mask having a corresponding pattern using an exposure device to selectively irradiate light (i.e., exposure process). Then, a developer solution is sprayed onto the mask to thereby form a pattern 600 including vias 601 for formation of the second nanoparticle film on the flexible substrate 100.

Step (j): Formation of Second Nanoparticle Film

When the pattern 600 is formed on the flexible substrate 100, a solution process, i.e., a spin-coating process is performed on the pattern 600 using a second nanoparticle solution to thereby form a second nanoparticle film layer 700 on one side of the flexible substrate including the pattern 600.

After the formation of the second nanoparticle film 700, the pattern 600 formed on the flexible substrate 100 is removed through a known lift-off process. If the pattern 600 is removed from the flexible substrate 100, the second nanoparticle films 60 formed at the positions of vias (i.e., through-holes) 601 are manufactured.

Step (k): Formation of Second Electrode Pattern

A pattern 800 including quadrangular vias 801 for the second electrode is formed on the flexible substrate 100 using a photolithography method. The vias 801 are disposed opposed to the first electrodes so as to be spaced apart from the first electrodes.

More specifically, as in the case of the first electrode, a photoresist liquid is applied on the flexible substrate 100, and light is allowed to pass through a mask having a corresponding pattern using an exposure device to selectively irradiate light (i.e., exposure process). Then, a developer solution is sprayed onto the mask to thereby form the pattern 800 including vias 801 for formation of the second electrode on the flexible substrate 100.

Step (l): Deposition of Second Electrode

When the pattern 800 is formed on the flexible substrate 100 in the same manner as in the first electrode deposition step, a conductive layer having a good electrical conductivity is deposited on the pattern 800 through a known vacuum thermal evaporation process or sputter deposition process to form a second electrode layer 900.

After the formation of the second electrode layer 900, the pattern 800 formed on the exhaust pipe 100 is removed through a known lift-off process. If the pattern 800 is removed from the exhaust pipe 100, second electrodes 30 formed at the positions of vias (i.e., through-holes) 801 are manufactured. The first nanoparticle film 50 and the second nanoparticle film 60 are connected at ends thereof to the second electrode 60 so as to be spaced apart from each other.

Steps (m) and (n): Formation of Protective Layer for Forming Heat Shielding Protective Layer

After the completion of the formation of the second electrode, a protective layer (i.e., passivation layer) may be formed between the first electrode and the second electrode. The protective layer (i.e., passivation layer) 901 may be formed as a silicon oxide film. The protective layer 901 serves to prevent introduction of foreign substances from the outside along with the thermal insulation effect.

The thermoelectric generator module of the present invention manufactured by the steps as described above can provide a structure in which a pattern 902 including vias 903 for formation of a heat shielding protective layer 901 is formed using the photolithography method as shown in FIGS. 13M and 13N and a material for the certain protective layer is coated on the pattern 902 to form the heat shielding protective layer 901 on the first and second nanoparticle films 50 and 60 between the first electrode 20 and the second electrode 30, thereby minimizing a degradation of the performance due to disturbance through the insulating properties and the heat shielding protective function.

The thermoelectric generator module of the present invention as constructed above can be applied to a wide range of fields in which heat and electricity are combined, such as an automobile part such as a temperature adjustment seat (e.g., climate C-ntr-l), a semiconductor (e.g., circulator, cooling plate), a biological product (e.g., blood analyzer, PCR, sample temperature cycling tester), a scientific field (spectrophotometer), an optical field (CCD cooling, infrared sensor cooling, laser diode cooling, SHG laser cooling), a computer field (CPU cooling), a home appliance (kimchi refrigerator, mini refrigerator, hot and cold water dispenser, wine refrigerator, rice container, dehumidifier), a power generation field (waste heat generator, remote power generation), etc. In addition, the thermoelectric generator module of the present invention can be modified in various manners within a range of forming a structure enabling the realization of a large-area module through a serial connection structure. Further, the inventive thermoelectric generator module may be utilized as a power source for a portable device such as a smart phone, a tablet or the like through generation of power using heat emitted from the human body by taking a structure in which the module is built in a exhaust pipe or a structure in which the module is built in a functional fiber as a flexible material.

While the configuration and operation of the hybrid thermoelectric generator module of the present invention and the method of manufacturing the same have been described in connection with the exemplary embodiments illustrated in the drawings, they are merely illustrative and the invention is not limited to these embodiments. It will be appreciated by a person having an ordinary skill in the art that various equivalent modifications and variations of the embodiments can be made without departing from the spirit and scope of the present invention. Therefore, the true technical scope of the present invention should be defined by the technical sprit of the appended claims.

What is claimed is:

1. A thermoelectric generator module including one or more module unit bodies disposed between a hot source and a cold source to serve as fundamental structures for performing thermoelectric power generation,
wherein the module unit bodies are disposed on a exhaust pipe interposed between the hot source and the cold source, and
wherein each of the module unit bodies comprises:
at least two first electrodes disposed at one of the hot source and the cold source so as to be spaced apart from each other;
a second electrode disposed at the other of the hot source and the cold source so as to be spaced apart from the first electrodes;
a first nanoparticle film configured to interconnect one of the first electrodes and the second electrode and composed of an n-type or p-type semiconductor; and
a second nanoparticle film composed of a conductor or semiconductor of a type different from the type of the semiconductor forming the first nanoparticle film, and the second nanoparticle film being connected at one end thereof to one of the two first electrodes and connected at the other end thereof to the second electrode so as to be space apart from the first nanoparticle film.

2. The thermoelectric generator module according to claim 1, wherein the first electrodes and the second electrode are disposed on a co-plane,
wherein at least one of the first electrodes is connected to one of first electrodes in an adjoining module unit body, and
wherein at least one of the first electrodes, the second electrode, the first nanoparticle film, and the second nanoparticle film of the module unit body forms a “ [symbol] ” shape.

3. The thermoelectric generator module according to claim 2, wherein the module unit bodies including the module unit body consisting of the first electrodes, the second electrode, the first nanoparticle film, and the second nanoparticle film, which form the “ [symbol] ” shape, are consecutively disposed in series on the exhaust pipe to capture any one heat source.

4. The thermoelectric generator module according to claim 1, wherein a heat shielding protective layer is disposed on one side of the exhaust pipe between the first electrodes and the second electrode.

5. The thermoelectric generator module according to claim 4, wherein the heat shielding protective layer comprises at least one of a ceramic based material such as ZrO₂, SiO₂, Al₂O₃, TiO₂, SiC or ZrO₂ and polymer.

6. The thermoelectric generator module according to claim 4, wherein the exhaust pipe is formed of any one selected from among Polydimethylsiloxane (PDMS), polyimide, polycarbonate, Poly(methyl methacrylate) (PMMA), cyclic olefin copolymer (COC), parylene, polyethylene terephthalate (PET), polybutylene terephthalate (PBT), polysilane, polysiloxane, polysilazane, polycarbosilane, polyacrylate, polymethacrylate, polymethylacrylate, polyethylacrylate, polyethylmetacrylate, cyclic olefin polymer (COP), polyethylene (PE), polyprophylene (PP), polystyrene (PS), polyoxymethylene (POM), poly(ether ether ketone) (PEEK), polyether sulfone (PES), polytetrafluoroethylene (PTFE), polyvinyl chloride (PVC), polyvinylidene fluoride (PVDF), and perfluoroalkyl ethyl acrylate (PFA), or a combination thereof.

7. The thermoelectric generator module according to claim 1, wherein the first nanoparticle film and the second nanoparticle film comprise a chalcogenide compound.

8. The thermoelectric generator module according to claim 7, wherein the first nanoparticle film comprises at least one chalcogenide compound selected from the group consisting of HgTe, Sb₂Te₃, Bi₂Te₃, and PbTe.

9. The thermoelectric generator module according to claim 7, wherein the second nanoparticle film 60 includes at least one chalcogenide compound selected from the group consisting of HgSe, Sb₂Se₃, Bi₂Se₃, PbSe, and PbS.

10. A method of manufacturing a thermoelectric generator module, the method comprising:
a nanoparticle solution provision step of providing a first nanoparticle solution comprising a first nanoparticle composed of an n-type or p-type semiconductor and a second nanoparticle solution comprising a second nanoparticle composed of a p-type or n-type semiconductor;
a first electrode pattern formation step of forming a pattern for deposition of a conductive layer for first electrodes by performing a photolithography process on a exhaust pipe;
a first electrode deposition step of depositing a conductive layer on the pattern 200 to form the first electrodes;
a first nanoparticle film pattern formation step of forming a pattern for formation of a first nanoparticle film connected to the first electrodes by performing the photolithography process on at least one of the first electrodes formed on the exhaust pipe;
a first nanoparticle film formation step of spin-coating the first nanoparticle solution on the pattern to form the first nanoparticle film;
a second nanoparticle film pattern formation step of forming a pattern for formation of a second nanoparticle film that is alternately arranged with the first nanoparticle film so as to be spaced apart from the first nanoparticle film and is connected to the first electrode by performing the photolithography process on at least one of the first electrodes;
a second nanoparticle film formation step of spin-coating the second nanoparticle solution on the pattern to form the second nanoparticle film;
a second electrode pattern formation step of forming a pattern for deposition of a conductive layer for the second electrode by performing a photolithography process on the other sides of the first and second nanoparticle films;
a second electrode deposition step of depositing a conductive layer on the pattern to form the second electrodes; and
a protective layer formation step of forming a heat shielding protective layer on the first and second nanoparticle films between the first electrode 300 and the second electrode.

11. The method according to claim 10, wherein the first nanoparticle solution and the second nanoparticle solution comprise a chalcogenide compound.

12. The method according to claim 11, wherein the first nanoparticle solution comprises at least one chalcogenide compound selected from the group consisting of HgTe, Sb₂Te₃, Bi₂Te₃, and PbTe.

13. The method according to claim 11, wherein the second nanoparticle solution comprises at least one chalcogenide compound selected from the group consisting of HgSe, Sb₂Se₃, Bi₂Se₃, PbSe, and PbS.

14. The method according to claim 11, wherein in the first nanoparticle film formation step and the second nanoparticle film formation step, the rotational speed of the exhaust pipe is in the range between the 500 rpm and 7000 rpm.

15. The method according to claim 14, wherein during the rotation of the exhaust pipe, a speed change of the exhaust pipe to predetermined different first and second rotational speeds occurs for a predetermined time,
wherein the first rotational speed is lower than the second rotational speed, and the rotation time of the first rotational speed is shorter than the rotation time of the second rotational speed, and
wherein the ratio of the first rotational speed to the second rotational speed is below 1:12, and the ratio of the rotation time of the first rotational speed to the rotation time of the second rotational speed is below 1:8.

16. A thermoelectric generator module manufactured by the method according to claim 10.

17. A thermoelectric generator module manufactured by the method according to claim 11.

18. A thermoelectric generator module manufactured by the method according to claim 12.

19. A thermoelectric generator module manufactured by the method according to claim 13.

20. A thermoelectric generator module manufactured by the method according to claim 14.
